(19) United States
(12) Patent Application Publication
(10) Pub. No.: US 2015/0083466 A1
(43) Pub. Date: Mar. 26, 2015

(54) Method For The Functionalisation Of Metal Nanowires And The Production Of Electrodes

(71) Applicants: Jean-Pierre Simonato, Sassenage (FR); Alexandre Carella, Mazeres Lezons (FR)

(72) Inventors: Jean-Pierre Simonato, Sassenage (FR); Alexandre Carella, Mazeres Lezons (FR)

(73) Assignee: Commissariat A L'Energie Atomique Et Aux Energies Alternatives, Paris (FR)

(21) Appl. No.: 14/233,964

(22) PCT Filed: Jul. 20, 2012
(86) PCT No.: PCT/IB2012/053719

§ 371 Date: Dec. 8, 2014

(30) Foreign Application Priority Data
Jul. 22, 2011 (FR) 11 56679

(51) Int. Cl. H01B 1/22; H05K 3/10; H05K 1/02; H05K 1/09; H01B 13/00; H01B 13/30

(52) U.S. Cl. CPC H01B 1/22; H01B 13/0026; H01B 13/30; H01B 13/0016; H05K 1/028; H05K 1/09; H05K 3/103; H05K 1/0306
USPC 174/253; 427/125; 427/123; 427/124; 524/548; 556/110; 174/126.2

(57) ABSTRACT

The invention relates to a method for the functionalisation of metal nanowires and the use of said nanowires. The functionalisation method of the invention includes a step comprising the formation of a self-assembled monolayer on at least part of the external surface of metal nanowires, using a compound of formula R¹—Zₙ—R², wherein Z is S or Se, and n is equal to 1 or 2, and R¹ is a hydrogen atom or an acyl group or a hydrocarbon group comprising between 1 and 100 carbon atoms and R² is an electron-attracting or -donating group. The method if the invention is particularly suitable for use in the field electrode production.

The invention relates to a process for the functionalization of metal nanowires and to a process for the manufacture of electrodes comprising such functionalized metal nanowires. It also relates to a device comprising these functionalized metal nanowires or at least one electrode comprising such functionalized metal nanowires.

Materials having an optimum combination of high electrical conductivity and of optical transparency are extremely important components in the development of many fields having high added value, such as photovoltaic cells, OLEDs and PLEDs, photodetectors and any electronic device involving the use of photons.

Today, most of materials of this type are transparent conductive oxides (TCOs) and in particular ITO (Indian Tin Oxide) or doped tin oxides. These products are derived from old patents, such as that of Corning, dating from the 1940s. However, the requirements for future optoelectronic devices are changing and it is henceforth essential to obtain films which can be obtained under milder conditions, for problems of compatibility, in particular with organic materials, but also by large-area printing techniques, in order to reduce the production costs, while improving some properties, such as the lightness or the mechanical flexibility.

The latter points (flexibility, printing, costs) are difficult to render compatible with deposited layers of ITO type, in particular as indium is a relatively rare element, the costs of which will very strongly increase, and because ITO does not exhibit favorable mechanical characteristics. Furthermore, TCOs are well known to a person skilled in the art to be brittle and easily damaged with bending and with mechanical stress in general. Finally, the majority of these processes are carried out under vacuum and, while the use of deposition by the liquid route is possible, it is subsequently essential to carry out high-temperature annealings in order to obtain the targeted electrical performances, which rules out the use of this process for plastic substrates, for example.

Another alternative is the use of conductive polymers, such as PEDOT:PSS. However, this material is sensitive, in particular to humidity and to high temperatures, and does not make it possible to have performances which are stable over time.

From the viewpoint of this balance sheet of existing technologies and of the need to find alternatives to the ITO, several routes have been developed which use nanomaterials.

The use of carbon nanotubes (CNTs) gives advantageous results but the electrical performance is still modest (generally in the vicinity of 1000 ohm/sq at 90% transmittance, measured at 550 nm). One problem is that the intrinsic conductivity, often very good, of unidimensional nanomaterials (for example nanowires, nanotubes, that is to say with a length/diameter aspect ratio >20) is not reencountered on a macroscopic scale when they are gathered together in the form of thin films (in a percolating network “or carpet” system). For example, the CNT-CNT contact resistances limit the overall conductivity of the CNT films.

It is the same for the graphene-based electrodes, which exhibit a performance which is still insufficient for the targeted applications.

Another possible approach is the preparation of electrodes based on metal nanowires. Very recently, it has been shown that very thin metal nanowires could be produced in solution from noble metals according to relatively simple procedures. The first results obtained in this direction demonstrate that conductive films starting from metal nanowires have a performance which is competitive (Hu et al. ACS Nano, 2010, 5, 2955-63) with ITO while being more flexible and having a manufacture compatible with low-temperature processes.

Several physical properties are very important for the incorporation of electrodes based on metal nanowires in (opto)electronic devices. The sheet resistance, the transmittance, the haze factor, the mechanical flexibility or the value of the work function are crucial factors which determine the performance of the electrodes and condition their use for such and such an application.

As regards the value of the work function, this value is particularly important when the electrode is brought into contact with another material having a different work function. This is because this can result in a resistance of Schottky type which is not desirable in some devices. In order to obtain an ohmic contact, it is necessary to align the energy levels of the electrode and of the material at its interface. For example, the organic or hybrid materials used in organic electronics, or the organic or hybrid materials exhibiting photoelectronic properties (for example, photovoltaics or photodetectors), have variable energy levels, typically between 4 and 6 eV, which it is necessary to adjust as best as possible with those of the electrodes.

Thus, one disadvantage related to the use of these electrodes is that the work function of the electrode is not necessarily suitable for the active materials with which these electrodes will be combined in the manufacture of a functional device.

In this context, the aim of the invention is to improve the ohmic contacts between the active layers of a device and the electrodes of this device by modifying the base conductive nanometric components which make up the electrodes, by the formation of a percolating network of metal nanowires by means of a chemical functionalized based on organic molecules.

The modification of the work function of electrodes composed of silver by the formation of a self-assembled monolayer (SAM) of aromatic thiol compounds has already been described by Hong et al. in Applied Physics Letters, 92, 143311 (2008).

However, in this document, the electrodes are composed of solid and thick silver films, the process for the manufacture of which is not transposable to the preparation of devices which are flexible and/or printable according to large-area printing techniques. This solution would thus appear to be a priori difficult to transpose to electrodes composed of a percolating network of silver nanowires and more generally metal nanowires as either the functionalization of the nanowires is carried out before they are dispersed in a solvent, which dispersion is necessary in order to be able to deposit them on a substrate, and in this case the self-assembled monolayer would form a screen between each nanowires so that the network deposited on the substrate would no longer percolate, or the nanowires are functionalized after they are dispersed when they are in the film form and, here again, this does not appear a priori to be able to be carried out as it is well known that nanowires after dispersion are covered with residue from the polymer used for the dispersing thereof, which would prevent the grafting of the molecules intended to form the self-assembled layer, or the nanowires.

EP 1 741 717 A1 describes gold nanobars, having an aspect ratio of 18, functionalized with a long-chain molecule (11 carbon atoms) and neutral from the electronic viewpoint, the role of which is to facilitate the dissolution of a medicinal active principle. Thus, the molecule grafted to the nanobars, in this document, does not make it possible to modify the electrostatic environment in the vicinity of the nanobar and thus does not make it possible to modify the work function of an electrode manufactured from these nanobars.

In point of fact, it has now been discovered that, surprisingly, nanowires, whether they are functionalized before or after the dispersing thereof, give electrodes having a work function which is indeed modified.

Thus, the invention provides a process for the functionalization of metal nanowires comprising a step of formation of a self-assembled monomolecular layer over at least a portion, preferably over at least 10%, of their external surface, characterized in that:
the nanowires are made of a metal chosen from silver (Ag), gold (Au), copper (Cu), platinum (Pt), palladium (Pd), nickel (Ni), cobalt (Co), rhodium (Rh), iridium (Ir), ruthenium (Ru) and iron (Fe), preferably chosen from Ag, Au and Cu, more preferably chosen from Ag and Au, and in that:
the self-assembled monomolecular layer is obtained by reaction of a compound of following formula (I):

R¹—Zₙ—R² =Formula (I)

in which:
Z represents a sulfur or selenium atom,
n=1 or 2,
R¹ represents a hydrogen atom, an acyl group or a saturated or unsaturated and linear, branched or cyclic hydrocarbon group comprising from 1 to 100 atoms and optionally comprising one or more heteroatoms and/or one or more chemical functional groups comprising at least one heteroatom; preferably, R¹ represents a hydrogen atom, an acyl group or a methyl, ethyl, propyl or butyl group,
R² represents:
   either an electron-withdrawing group, preferably a saturated or unsaturated, aromatic or nonaromatic and linear, branched or cyclic hydrocarbon group completely or partially substituted by nitro, trifluoromethyl, cyano, amide, ester, carboxylic acid, halide or 2-dicyanomethylene-3-cyano-2,5-dihydrofuran groups and/or comprising at least one fluorine atom,
   or an electron-donating group, preferably a linear or branched, cyclic and/or aromatic, hydrocarbon group completely or partially substituted by alkoxy, amine or thioether groups, and
R¹ and R² can be identical or different.

In a first embodiment of the functionalization process of the invention, in the compound of formula (I), R² is an electron-withdrawing group and the compound of formula (I) is chosen from para-(trifluoromethyl)thiophenol, 3,5-bis(trifluoromethyl)thiophenol, pentafluorothiophenol, pentafluoroselenophenol, perfluorododecanethiol, perfluorooctadecanethiol, para-nitrothiophenol, para-cyanothiophenol, 3,5-dinitrothiophenol and 3,5-dicyanothiophenol.

In a second embodiment of the functionalization process of the invention, in the compound of formula (I), R² is an electron-donating group and the compound of formula (I) is chosen from para-methoxythiophenol, 3,5-dimethoxythiophenol, para-methoxyselenophenol, para-thiomethylthiophenol, dimethyl disulfide, di(para-methoxyphenyl)disulfide, diethyl sulfide or butanethiol.

In all the embodiments of the functionalization process of the invention, the nanowires preferably have an aspect ratio (length/diameter ratio) of greater than or equal to 20, preferably of between 20 and 50000 and more preferably of between 100 and 10000.

The invention also provides a process for the manufacture of electrodes, characterized in that it comprises the following steps:

a) dispersion of metal nanowires made of a metal chosen from silver (Ag), gold (Au), copper (Cu), platinum (Pt), palladium (Pd), nickel (Ni), cobalt (Co), rhodium (Rh), iridium (Ir), ruthenium (Ru) and iron (Fe) in a solvent preferably chosen from water, methanol, ethanol, hexane, toluene, xylene, chlorobenzene, dichlorobenzene, tetrahydrofuran and N-methylpyrrolidone, and the mixtures of two or more of these,
b) functionalization of the metal nanowires by the process according to the invention, and
c) deposition on a substrate of the functionalized nanowires obtained in step b) or of the nonfunctionalized nanowires of step a).

In a first embodiment of the process for the manufacture of electrodes of the invention, step c) is carried out before step b), in which case the nonfunctionalized nanowires are first deposited on the substrate in step c) and are functionalized subsequently in step b).

In a second embodiment of the process for the manufacture of electrodes of the invention, step b) is carried out before step c), in which case the nanowires deposited in step c) are already functionalized.

In all the embodiments of the process for the manufacture of electrodes of the invention and in a first alternative form, the substrate is a rigid substrate.

In all the embodiments of the process for the manufacture of electrodes of the invention and in a second alternative form, the substrate is a flexible substrate.

The substrate can be made of a material chosen from glass, a woven or nonwoven textile, plastic or a foam.

Examples of plastics which can be used to form the substrate are polyethylene terephthalate (PET), polyethylene naphthalate (PEN), a polyimide, a polyamide 6 or a polyamide 6,6, polyethylene (PE) or polypropylene (PP). The textiles which can be used to form the substrate are woven or nonwoven textiles of polyamide, polyester, cotton or flax fibers. The foams which can be used as substrates are polyurethane or rubber foams.

In all its embodiments and its alternative forms, the process for the manufacture of electrodes of the invention can additionally comprise, before step c) of deposition of the metal nanowires on the substrate, a step d) of treatment of the substrate surface, preferably by application of a layer of paint, of an anticorrosion material, of a hydrophilic material, of a water-repellent material and/or of a flame-repellent material.

Still in all the embodiments and the alternative forms of the process for the manufacture of electrodes of the invention, step c) of deposition of the nanowires is a step of deposition by vaporization, by inkjet printing, by spin coating, by flexography, by photogravure or with a scraper.

In all its embodiments and its alternative forms, the process for the manufacture of electrodes of the invention can additionally comprise a step e) of evaporation of the solvent of the dispersion obtained in step a), after steps a), b) and c).

Also in all its embodiments and its alternative forms, the process for the manufacture of electrodes of the invention can additionally comprise a step f) of heat treatment of the network of functionalized metal nanowires deposited on the substrate, at a temperature of between 50° C. and 300° C., limits included.

Finally, in all its embodiments and its alternative forms, the process for the manufacture of electrodes of the invention can additionally comprise a step g) of covering the substrate coated with the functionalized metal nanowires, forming the electrodes, with encapsulation materials, preferably with a fluoropolymer or a silicone polymer, or a mixture of these.

The invention also provides a device, characterized in that it comprises metal nanowires obtained by the functionalization process according to the invention.

The invention also provides a device, characterized in that it comprises at least one electrode obtained by the process for the manufacture of electrodes according to the invention.

Finally, the invention provides for the use of functionalized nanowires obtained by the functionalization process according to the invention in the manufacture of electrodes.

A better understanding of the invention will be obtained and other advantages and characteristics of the invention will become more clearly apparent on reading the explanatory description which follows.

The invention relates to the use of metal nanowires functionalized with organic molecules in the manufacture of electrodes, in particular transparent electrodes, which are optionally flexible.

The term “metal nanowires functionalized by molecules” is intended to mean objects comprising a central part composed of metal nanowires, the radius of which is less than 100 nm and the length of which is between 1 and 500 lam, and the surface of which is at least partially coated with a self-assembled layer. The metals used are preferably Ag, Au, Cu, Pt, Pd, Ni, Co, Rh, Ir, Ru or Fe, and more preferably Ag, Au or Cu.

These nanowires are, for example, obtained in solution. The synthesis of nanowires is carried out starting from reduced metal precursors in solution. For example, for silver nanowires, use may be made of the method described in Hu et al., ACS Nano, 2010, 5, 2955-63 and, for gold nanowires, use may be made of that described in Lu et al., J. Am. Chem. Soc., 2008, 130, 8900-8901.

The process for the functionalization of the metal nanowires of the invention comprises a step of formation, on the surfaces of the nanowires, of a self-assembled monomolecular layer starting from one or more precursors of the following formula (I):

R¹—Zₙ—R² Formula (I)

in which:
Z represents a sulfur or selenium atom,
n=1 or 2,
R¹ represents a hydrogen atom or a saturated or unsaturated and linear, branched or cyclic hydrocarbon group which is optionally perfluorinated or partially fluorinated, which comprises from 1 to 100 carbon atoms and which optionally comprises one or more heteroatoms,
R² represents either an electron-withdrawing group, preferably a saturated or unsaturated, aromatic or nonaromatic and linear, branched or cyclic hydrocarbon group which is completely or partially substituted by nitro, trifluoromethyl, cyano, amide, ester, carboxylic acid, halide or 2-dicyanomethylene-3-cyano-2,5-dihydrofuran groups or which comprises a fluorine atom, or an electron-donating group, preferably a linear or branched, cyclic and/or aromatic, hydrocarbon group which is completely or partially substituted by alkoxy, amine or thioether groups.

R¹ and R² can be identical or different.

Preferably, R¹ is chosen from a hydrogen atom, an acyl group or a methyl, ethyl, propyl or butyl group.

This functionalization can completely or partially cover the surface of the nanowires. When it only partially covers the surface of the nanowires, the functionalization covers at least 10% of this surface.

One possible procedure for functionalizing the nanowires consists in dispersing the nanowires in a solvent. The solvents which can be used are alcohols, water, ketones, in particular acetone, amines, ethers, alkylaromatic or haloaromatic solvents, N-methylpyrrolidone or dimethylformamide. The preferred solvents are water, methanol, ethanol, hexane, toluene, xylene, chlorobenzene, dichlorobenzene, tetrahydrofuran, N-methylpyrrolidone or mixtures of two or more of these. By addition of the compound of formula (I) to the solution, a monomolecular layer is formed on the surface of the nanowires.

The grafting of the molecules of formula (I) can also be carried out by exchange of ligands, that is to say that the molecules of formula (I) can replace any organic entity initially present around the nanowires (before the addition of the compound of formula (I)).

The preferred molecules with formula (I) used in the process for the functionalization of metal nanowires of the invention are, when the R² group is an electron-withdrawing group, chosen from para-(trifluoromethyl)thiophenol, 3,5-bis(trifluoromethyl)thiophenol, pentafluorothiophenol, pentafluoroselenophenol, perfluorododecanethiol, perfluorooctadecanethiol, para-nitrothiophenol, para-cyanothiophenol, 3,5-dinitrothiophenol and 3,5-dicyanothiophenol.

The preferred molecules with which the metal nanowires of the invention are functionalized, when the R² group is an electron-donating group, are para-methoxythiophenol, 3,5-dimethoxythiophenol, para-methoxyselenophenol, para-thiomethylthiophenol, dimethyl disulfide and di(para-methoxyphenyl)disulfide.

The invention also relates to a process for the manufacture of electrodes, in particular transparent electrodes, which are optionally flexible, produced starting from the functionalized metal nanowires according to the invention.

This process comprises the following steps:

a) dispersion of metal nanowires made of a metal chosen from silver (Ag), gold (Au), copper (Cu), platinum (Pt), palladium (Pd), nickel (Ni), cobalt (Co), rhodium (Rh), iridium (Ir), ruthenium (Ru) and iron (Fe) in a solvent preferably chosen from water, methanol, hexane, toluene, acetone and the mixtures of two or more of these,
b) functionalization of the metal nanowires by the functionalization process of the invention, and
c) deposition of the nanowires on a substrate.

In a first alternative form of the process for the manufacture of electrodes according to the invention, the metal nanowires are already functionalized by the molecules of formula (I) before they are deposited on the surface of the substrate of the electrode. The electrode is then composed of a percolating network of metal nanowires functionalized by molecules of formula (I). A preferred method for depositing the functionalized nanowires on the surface of the substrate consists in vaporizing a dispersion comprising the metal nanowires functionalized by the process of the invention, that is to say in generating microdroplets comprising the functionalized metal nanowires, and in spraying them, under pressure or electrical stress, onto the desired substrate.

In a second alternative form, the nonfunctionalized metal nanowires are first deposited on the surface of the substrate forming the electrode. At this step, the electrode is composed of a percolating network of nonfunctionalized metal nanowires.

The functionalization of the nanowires is then carried out. This functionalization is carried out as described above: the electrode and its substrate are brought into contact with the molecules of formula (I). The contacting operation can be carried out by dipping in a solution comprising one or more molecules of formula (I), preferably by spraying the solution over the electrodes.

In the first alternative form, as in the second alternative form, of the process for the manufacture of electrodes according to the invention, the functionalized or nonfunctionalized metal nanowires can be deposited on the surface of the substrate by vaporization, inkjet printing, spin coating or by other techniques of flexography, photogravure or deposition with a scraper.

The substrate of the electrodes on which the functionalized or nonfunctionalized metal nanowires are deposited can be extremely varied: it can, for example, be plastic, glass, woven or nonwoven textile, a foam, and the like.

When it is desired to obtain flexible electrodes, the thickness and/or the nature of the substrate will be varied.

This substrate can optionally be treated before the deposition of the nanowires, for example by deposition of a surface layer based on paint, on an anticorrosion product or on a flame-retardant, hydrophilic or hydrophobic coating.

The solvent of the dispersion comprising the nanowires which are deposited is preferably water, methanol, hexane, toluene, acetone or a mixture of two or more of these.

This solvent is evaporated, if need be, by heating the substrate, after the deposition of the functionalized nanowires in the first embodiment of the invention, or in the second embodiment of the invention, optionally under vacuum.

In order to improve the performance of the electrodes obtained by the process of the invention, it may be necessary to reanneal the network of deposited nanowires, at a temperature of between 50 and 300° C., limits included.

In the second alternative form of the manufacturing process according to the invention, the functionalization of the nanowires after they have been deposited on the surface of the substrate can be carried out by dipping the substrate, covered with the nanowires, in a solution comprising one or more molecules of formula (I) by spraying the solution over the electrodes by vaporization or inkjet printing. Another technique consists in placing electrodes in a space comprising molecules of formula (I), for example at their saturated vapor pressure.

In all the alternative forms of the process for the manufacture of the electrodes according to the invention, the electrodes can be used as is or covered with an encapsulating material, such as a polymer, for example a fluoropolymer and/or a polymer of silicone type.

The electrodes obtained by the use of molecules of formula (I) in which the R² group is an electron-withdrawing group leads to the increase in the work function of these electrodes. By way of example, when the nanowires are made of silver and functionalized, the work function of the electrodes obtained is greater than 5 eV, whereas the work function of electrodes formed from silver nanowires devoid of functionalization is approximately 4.7 eV.

Conversely, the use of molecules of formula (I) in which R² is an electron-donating group results in a decrease in the work function of the electrodes obtained by the process of the invention, that is to say to values lower than those of electrodes formed of nonfunctionalized silver nanowires. Typically, the values of the work function of the electrodes manufactured by the process of the invention with silver nanowires functionalized with molecules of formula (I) for which the R² group is electron-donating is 4.5 eV, whereas the work function of electrodes manufactured from nonfunctionalized silver nanowires is approximately 4.7 eV.

In the processes of the invention, the nanowires have an aspect ratio, that is to say a length/diameter ratio, of greater than or equal to 20. More preferably, this aspect ratio is between 20 and 50000.

More preferably still, this aspect ratio is between 100 and 10000. This is because, for an application as electrode, the use of nanowires having a high aspect ratio makes it possible to obtain a more efficient and more transparent percolating system with fewer conductive nanowires. The “meshing” thus obtained with nanowires having a high aspect ratio is a little too broad but, by using fewer nanowires (ideally having smaller diameters), the light is allowed to pass better (improved transparency) and the number of interwire connections is increased.

In order to make the invention better understood, several embodiments thereof will now be described as purely illustrative and nonlimiting examples.

### EXAMPLE 1

Silver nanowires are manufactured according to the following process:

1.766 g of PVP (polyvinylpyrrolidone) are added to 2.6 mg of NaCl (sodium chloride) in 40 ml of EG (ethylene glycol). The mixture is stirred at 600 rpm at 120° C. until the PVP+NaCl has completely dissolved (approximately 4-5 minutes). This mixture is added dropwise, using a dropping funnel, to a solution of 40 ml of EG in which 0.68 g of AgNO₃ (silver nitrate) is dissolved. The oil bath is heated to 160° C. and stirring is allowed to take place at 700 rpm for 80 minutes. Three washing operations are carried out with methanol, centrifuging being carried out at 2000 rpm for 20 min, and then the nanowires are precipitated with acetone and, finally, redispersed in water.

The electrodes are manufactured by depositing the nanowires manufactured above on substrates consisting of a square 4 cm×4 cm glass plate, by vaporization using an Aztek A4709 airbrush.

The plates obtained are dipped for 10 min in a 50 mM solution of thiophenol in toluene, then rinsed with acetone and dried under argon.

The plates obtained have a sheet resistance of between 15 and 40 ohm/sq for a transmittance between 78 and 82% (at 550 nm).

### EXAMPLE 2

The procedure was carried out as in example 1 but, during the manufacture of the silver nanowires, the latter are precipitated with acetone and redispersed in methanol and not water.

The plates obtained have a sheet resistance of between 15 and 40 ohm/sq for a transmittance of between 78 and 82% (at 550 nm).

### EXAMPLE 3

The procedure was carried out as in example 1 but the nanowires were deposited on square 4 cm×4 cm polyethylene terephthalate (PET) plates by spin coating.

The plates obtained have a sheet resistance of between 15 and 40 ohm/sq for a transmittance of between 78 and 82%.

### COMPARATIVE EXAMPLE 1

The silver nanowires were manufactured as in example 1.

Electrodes were obtained by deposition of these nanowires on square 4 cm×4 cm glass plates by vaporization of the dispersion using an Aztek A4709 airbrush.

However, the silver nanowires of the electrodes obtained are not, as in the case of example 1, functionalized.

The plates obtained have a sheet resistance of between 15 and 40 ohm/sq for a transmittance of between 78 and 82%.

### COMPARATIVE EXAMPLE 2

Silver nanowires were manufactured by the same process as in example 2.

These nanowires were deposited on square 4 cm×4 cm glass plates by vaporization of the dispersion of nanowires obtained above using an Astek A4709 airbrush.

However, contrary to example 2, the silver nanowires of these electrodes are not functionalized.

The plates obtained have a sheet resistance of between 15 and 40 ohm/sq for a transmittance of between 78 and 82%.

### COMPARATIVE EXAMPLE 3

The procedure was carried out as in example 3 but without the step of functionalization of the silver nanowires.

The plates obtained have a sheet resistance of between 15 and 40 ohm/sq.

KPFM (Kelvin probe force microscopy) measurements were carried out on each of the plates obtained in examples 1 to 3 and in comparative examples 1 to 3.

These measurements show a shift in the work function between the electrodes obtained in example 1 and in comparative example 1, between the electrodes obtained in example 2 and in comparative example 2 and between the electrodes obtained in example 3 and in comparative example 3 of +0.6 electron volts for the electrodes obtained by the process of the invention.

### EXAMPLE 4

Gold nanowires are manufactured according to the following process:

400 μl of HAuCl₄ (30% in HCl) are added to 2 ml of hexane and 10 ml of OA (oleylamine) at 80° C. Vigorous stirring is allowed to take place for 5 min and the mixture is left at this temperature, the stirring being switched off, for 5 h. The reaction mixture becomes bright red. A precipitate (deep black product) is obtained by adding ethanol. After centrifuging at 3400 rev.min⁻¹ and washing with ethanol for 10 min, the nanowires are dispersed in hexane.

The electrodes are manufactured by depositing these nanowires on a square 4 cm×4 cm glass plate.

The plates are subsequently placed on a heating plate at 80° C. A 20 mM solution of 4-methoxythiophenol in toluene is vaporized using the Aztek A4709 airbrush for 10 seconds. The plates are left to dry under air for 30 min.

The plates obtained have a sheet resistance of between 30 and 50 ohm/sq for a transmittance of between 75 and 78% (at 550 nm).

### EXAMPLE 5

The procedure was carried out as in example 4 except that the gold nanowires are deposited on polyethylene terephthalate plates.

The plates obtained have a sheet resistance of between 30 and 50 ohm/sq for a transmittance of between 75 and 78% (at 550 nm).

### COMPARATIVE EXAMPLE 4

Gold nanowires were manufactured by the same process as in example 4. The electrodes were then manufactured by vaporization of the dispersion of these gold nanowires over glass plates having the same dimensions as in example 4 and by vaporization of the dispersion using the Aztek A4709 airbrush.

However, unlike example 4, in this example, the gold nanowires were not subsequently functionalized. The glass plates on which the gold nanowires were deposited are simply placed on a heating plate at 80° C. Pure toluene is vaporized over these plates using the Aztek A4709 airbrush for 10 seconds.

The plates are subsequently left to dry under air for 30 min.

The plates obtained have a sheet resistance of between 30 and 50 ohm/sq for a transmittance of between 15 and 78% (at 550 nm).

### COMPARATIVE EXAMPLE 5

The procedure was carried out as in example 5, except that the gold nanowires were not functionalized. The plates obtained after the deposition of the gold nanowires were placed on a heating plate at 80° C. and vaporized with pure toluene using the Aztek A4709 airbrush for 10 seconds. They were then left to dry under air for 30 min.

The plates obtained have a sheet resistance of between 30 and 50 ohm/sq for a transmittance of between 75 and 78% (at 550 nm).

KPFM measurements were carried out on each of the plates obtained in examples 4 and 5 and in comparative examples 4 and 5.

They show a shift in the work function of the electrodes respectively obtained in example 4 and in comparative example 4 and between the electrodes obtained in example 5 and in comparative example 5 of −1 eV.

### EXAMPLE 6

Silver nanowires are manufactured according to the following process:

1.766 g of PVP (polyvinylpyrrolidone) are added to 2.6 mg of NaCl (sodium chloride) in 40 ml of EG (ethylene glycol). The mixture is stirred at 600 rpm at 120° C. until the PVP+NaCl has completely dissolved (approximately 4-5 minutes). This mixture is added dropwise, using a dropping funnel, to a solution of 40 ml of EG (ethylene glycol) in which 0.68 g of AgNO₃ (silver nitrate) is dissolved. The oil bath is heated to 160° C. and stirring is allowed to take place at 700 rpm for 80 minutes. Three washing operations are carried out with methanol, centrifuging being carried out at 2000 rpm for 20 min, and then the nanowires are precipitated with acetone and, finally, redispersed in methanol.

Pentafluorothiophenol is added to the methanolic solution of nanowires at a concentration of 10 mM. The solution is left standing at ambient temperature for 12 h.

Electrodes are manufactured by depositing the nanowires manufactured above on substrates consisting of a square 4 cm×4 cm glass plate, by evaporation using an Aztek A4709 airbrush.

The plates obtained have a sheet resistance of between 18 and 40 ohm/sq for a transmittance of between 77 and 82% (at 550 nm) and exhibit a work function of 5.4 eV (versus 4.7 eV for nonfunctionalized nanowires (comparative example 1)).

### EXAMPLE 7

Copper nanowires were prepared according to the method described by Zheng in Chemistry Letters, Vol. 35, No. 10 (2006), page 1142. Electrodes are manufactured by depositing these nanowires on substrates consisting of a square 4 cm×4 cm glass plate, by vaporization using an Aztek A4709 airbrush.

The plates obtained are dipped in dry toluene for 10 min, then rinsed with acetone and dried under argon.

The plates obtained have a sheet resistance of between 20 and 200 ohm/sq for a transmittance of between 52 and 77% (at 550 nm).

### COMPARATIVE EXAMPLE 7

Copper nanowires were prepared according to the method described by Zheng in Chemistry Letters, Vol. 35, No. 10 (2006), page 1142. Electrodes are manufactured by depositing these nanowires on substrates consisting of a square 4 cm×4 cm glass plate, by vaporization using an Aztek A4709 airbrush.

The plates obtained are dipped in a 50 mM solution of perfluorothiophenol in toluene for 10 min, then rinsed with acetone and dried under argon.

The plates obtained have a sheet resistance of between 20 and 200 ohm/sq for a transmittance between 52 and 77% (at 550 nm).

KPFM measurements were carried out on each of the plates obtained in example 7 and in comparative example 7.

They show a shift in the work function between the electrodes obtained in example 7 and in comparative example 7 of −0.9 eV.

Thus, it is seen that the invention comes within a strong industrial and scientific context since the demand for electrodes, in particular transparent electrodes, has experienced significant growth. The electrodes of the invention, and the nanowires, obtained by the processes of the invention can be used in numerous applications, such as touch screens, flexible display panels, flexible photovoltaic cells, flexible photon detectors, large-area flexible electronics, and the like.

1. A process for the functionalization of metal nanowires comprising a step of formation of a self-assembled monomolecular layer over at least a portion of their external surface, wherein:
the nanowires are made of a metal chosen from silver (Ag), gold (Au), copper (Cu), platinum (Pt), palladium (Pd), nickel (Ni), cobalt (Co), rhodium (Rh), iridium (Ir), ruthenium (Ru) and iron (Fe),
and in that:
the self-assembled monomolecular layer is obtained by reaction of a compound of following formula (I):
R¹—Zₙ—R² =Formula (I)
in which:
Z represents a sulfur or selenium atom,
n=1 or 2,
R¹ represents a hydrogen atom, an acyl group or a saturated or unsaturated and linear, branched or cyclic hydrocarbon group comprising from 1 to 100 atoms and optionally comprising one or more heteroatoms;
R² represents:
either an electron-withdrawing group chosen from a saturated or unsaturated, aromatic or nonaromatic and linear, branched or cyclic hydrocarbon group completely or partially substituted by nitro, trifluoromethyl, cyano, amide, ester, carboxylic acid, halide or 2-dicyanomethylene-3-cyano-2,5-dihydrofuran groups and/or comprising at least one fluorine atom,
or an electron-donating group chosen from a linear or branched, cyclic and/or aromatic, hydrocarbon group completely or partially substituted by alkoxy, amine or thioether groups, and
R¹ and R² can be identical or different.

2. The process as claimed in claim 1, wherein the compound of formula (I), R² is an electron-withdrawing group and in that the compound of formula (I) is chosen from para-(trifluoromethyl)thiophenol, 3,5-bis(trifluoromethyl)thiophenol, pentafluorothiophenol, pentafluoroselenophenol, perfluorododecanethiol, perfluorooctadecanethiol, para-nitrothiophenol, para-cyanothiophenol, 3,5-dinitrothiophenol and 3,5-dicyanothiophenol.

3. The process as claimed in claim 1, wherein the compound of formula (I), R² is an electron-donating group and in that the compound of formula (I) is chosen from para-methoxythiophenol, 3,5-dimethoxythiophenol, para-methoxyselenophenol, para-thiomethylthiophenol, dimethyl disulfide, di(para-methoxyphenyl)disulfide, diethyl sulfide or butanethiol.

4. The process as claimed in claim 1, wherein the nanowires have an aspect ratio (length/diameter ratio) of greater than or equal to 20.

5. A process for the manufacture of electrodes, wherein the process comprises the following steps:
a) dispersion of metal nanowires made of a metal chosen from silver (Ag), gold (Au), copper (Cu), platinum (Pt), palladium (Pd), nickel (Ni), cobalt (Co), rhodium (Rh), iridium (Ir), ruthenium (Ru) and iron (Fe) in a solvent chosen from water, methanol, ethanol, hexane, toluene, xylene, chlorobenzene, dichlorobenzene, tetrahydrofuran, N-methylpyrrolidone, and the mixtures of two or more of these,
b) functionalization of the metal nanowires by the process as claimed in claim 1,
c) deposition on a substrate of the functionalized nanowires obtained in step b) or of the nonfunctionalized nanowires of step a).

6. The process as claimed in claim 5, wherein step c) is carried out before step b), in which case these nanowires, deposited on the substrate in step c), are not functionalized and are functionalized subsequently in step b).

7. The process as claimed in claim 5, wherein step b) is carried out before step c), in which case the nanowires deposited in step c) are already functionalized before they are deposited on the substrate.

8. The process as claimed in claim 5, wherein the substrate is a rigid substrate.

9. The process as claimed in claim 5, wherein the substrate is a flexible substrate.

10. The process as claimed in claim 5, wherein the substrate is a material chosen from glass, a woven or nonwoven textile, plastic or a foam.

11. The process as claimed in claim 5, wherein the process additionally comprises, before step c) of deposition of the metal nanowires on the substrate, a step d) of treatment of the substrate surface, by application of a layer of paint, of an anticorrosion material, of a hydrophilic material, of a water-repellent material and/or of a flame-repellent material.

12. The process as claimed in claim 5, wherein step c) of deposition of the nanowires is a step of deposition by vaporization, by inkjet printing, by spin coating, by flexography, by photogravure or with a scraper.

13. The process as claimed in claim 5, wherein the process additionally comprises a step e) of evaporation of the solvent of the dispersion obtained in step a), after steps a), b) and c).

14. The process as claimed in claim 5, wherein the process additionally comprises a step f) of heat treatment of the network of functionalized metal nanowires deposited on the substrate, at a temperature of between 50° C. and 300° C., limits included.

15. The process as claimed in claim 5, wherein the process additionally comprises a step g) of covering the substrate coated with the functionalized metal nanowires, forming the electrodes, with encapsulation materials, preferably with a fluoropolymer or a silicone polymer, or a mixture of these.

16. A device comprising metal nanowires obtained by the process as claimed in claim 1.

17. A device comprising at least one electrode obtained by the process as claimed in claim 5.

18. The use of functionalized nanowires obtained by the process as claimed in claim 1 in the manufacture of electrodes.

19. The process of claim 1, wherein R¹ represents a hydrogen atom, an acyl group or a methyl, ethyl, propyl or butyl group.
